(19) United States
(12) Patent Application Publication
(10) Pub. No.: US 2026/0065726 A1
(43) Pub. Date: Mar. 5, 2026

(54) TRUCK NETWORK FAILURE PREDICTION SYSTEM

(71) Applicant: Hale Products, Inc., Collegeville, PA (US)

(72) Inventor: Michael A. LASKARIS, Collegeville, PA (US)

(21) Appl. No.: 19/218,929

(22) Filed: May 27, 2025

Related U.S. Application Data
(60) Provisional application No. 63/651,581, filed on May 24, 2024.

(51) Int. Cl. G07C 5/08; B60R 16/023; G01R 31/00; G07C 5/00

(52) U.S. Cl. CPC G07C 5/0825; B60R 16/0232; G01R 31/006; G07C 5/008; G07C 5/0808

(57) ABSTRACT

A system for monitoring a vehicle CAN includes a measurement module power source, an electrical meter connected across the CAN and configured to detect an electrical characteristic of the CAN, a memory configured to store one or more prior measurements of the electrical characteristic, and a controller connected to the measurement module power source, the electrical meter, and the memory. The controller is configured to, when the vehicle is powered off and the controller is powered by the measurement module power source: receive a present measurement of the electrical characteristic of the CAN from the electrical meter, determine, based on the present measurement and the one or more prior measurements, whether the electrical characteristic is approaching an edge of a predetermined operational range for the electrical characteristic, and output a deterioration warning when the electrical characteristic is found to be approaching the edge of the predetermined operational range.

### CROSS-REFERENCE TO RELATED APPLICATIONS

This application claims the benefit of U.S. Provisional Patent Application No. 63/651,581, filed May 24, 2024, entitled “Truck Network Failure Prediction System,” currently pending, the entire contents of which are incorporated by reference herein.

### BACKGROUND

Embodiments described herein relate generally to controller area networks in a vehicle, and more particularly, to a system for evaluating controller area networks to avoid unexpected failures.

Complex vehicles such as fire trucks often have several controller area networks (CANs) moving data for various systems. The chassis might have one network connecting the engine, transmission, and antilock brakes. Additionally, a pump control system of the fire truck may have its own network controlling valves, the fire pump, and related systems, while additionally a foam chemical agent injection system may have its own network. The aerial ladder system of hydraulic controls is also often controlled via its own CAN. Fire trucks in particular, because they come in many specific configurations, have different network configurations from truck to truck. This can make them difficult to maintain and diagnose.

Society of Automotive Engineers (SAE) standard J1939 prescribes specifications for the physical layer of the CANs in vehicles. One such requirement is a specific resistance across the high and low legs of the bus. One of the most prominent forms of potential failure is the ingress of moisture into connectors, which affects bus resistance. Physical deterioration of electrical connections can also affect the bus resistance and cause communication errors that can prevent proper system operation.

When there is a suspected problem on a vehicle CAN, one of the first things to check is the resistance on the bus as part of basic troubleshooting, which is done when the vehicle is off. While the vehicle is powered up and operating, the CANs previously could not have the network resistance checked or the continuity as the data pulse train is running through the network (which means there is an average level of voltage on the bus and the resistance was not checked with the network operating, but when it was quiet/off).

It is desirable to provide a system that allows the CANs to be evaluated in such a manner that failures can be predicted prior to occurrence to prevent unnecessary and unwanted downtime of network systems during critical operating periods of the vehicle. It is further desirable to provide probable locations of faults and other problems causing such failures and deteriorations so they can more easily be addressed.

### BRIEF SUMMARY

Briefly stated, one example embodiment comprises a system for monitoring a controller area network (CAN) of a vehicle. The CAN has a high line and a low line that are connected to one another across two resistive element terminals. The CAN is connected to one or more nodes configured to send and/or receive communication over the CAN. The system includes a measurement module power source, an electrical meter connected across the CAN and configured to detect an electrical characteristic of the CAN, a memory configured to store one or more prior measurements of the electrical characteristic by the electrical meter, and a controller connected to the measurement module power source, the electrical meter, and the memory. The controller is configured to, when the vehicle is powered off and the controller is powered by the measurement module power source: (a) receive a present measurement of the electrical characteristic of the CAN from the electrical meter, (b) determine, based on the present measurement and the one or more prior measurements, whether the electrical characteristic is approaching an edge of a predetermined operational range for the electrical characteristic, and (c) output a deterioration warning when the electrical characteristic is found to be approaching the edge of the predetermined operational range.

In one aspect, the electrical characteristic is resistance. In a further aspect, the electrical meter is an ohmmeter.

In another aspect, the system further includes a communication port connected to the controller. In a further aspect, the communication port is configured to connect to a network, and the controller outputs the deterioration to the communication port for sending to an external device via the network.

In yet another aspect, the controller is further configured to: (d) determine whether the present measurement is outside of the predetermined operational range, and (e) output a failure alert when the present measurement is found to be outside of the predetermined operational range.

In still another aspect, the controller is configured to output the deterioration warning to a vehicle display output.

Another example embodiment comprises a system for monitoring a controller area network (CAN) of a vehicle. The CAN has a high line and a low line that are connected to one another across two resistive element terminals. The CAN is connected to one or more nodes configured to send and/or receive communication over the CAN. The system includes an alternating current (AC) signal generator connected to the CAN and configured to superimpose an AC waveform over pulse signals communicated over the CAN, an electrical meter connected to the CAN and configured to detect an electrical characteristic of the CAN, a memory configured to store one or more prior measurements of the electrical characteristic by the electrical meter, and a controller connected to the AC signal generator, the electrical meter, and the memory. The controller is configured to: (a) receive a present measurement of the electrical characteristic of the CAN from the electrical meter based on the superimposed AC waveform, (b) determine, based on the present measurement and the one or more prior measurements, whether the electrical characteristic is approaching an edge of a predetermined operational range for the electrical characteristic, and (c) output a deterioration warning when the electrical characteristic is found to be approaching the edge of the predetermined operational range.

In one aspect, the electrical characteristic is impedance. In a further aspect, the electrical meter is an ohmmeter. In a still further aspect, the system includes a measurement shunt connected between the ohmmeter and the CAN.

In another aspect, the system further includes an isolation transformer connected between the AC signal generator and the CAN.

In still another aspect, the controller is further configured to: (d) determine whether the present measurement is outside of the predetermined operational range, and (e) output a failure alert when the present measurement is found to be outside of the predetermined operational range.

Yet another example embodiment comprises a method of monitoring a controller area network (CAN) of a vehicle. The CAN has a high line and a low line that are connected to one another across two resistive element terminals. The CAN is connected to one or more nodes configured to send and/or receive communication over the CAN. The method includes: (a) receiving, by a controller from an electrical meter, a present measurement of an electrical characteristic of the CAN, (b) retrieving, by the controller from a memory, one or more prior measurements of the electrical characteristic, (c) determining, by the controller, based on the present measurement and the one or more prior measurements, whether the electrical characteristic is approaching an edge of a predetermined operational range for the electrical characteristic, and (d) outputting, by the controller, a deterioration warning when the electrical characteristic is found to be approaching the edge of the predetermined operational range.

In one aspect, the controller performs steps (a)-(d) while the vehicle is powered off and the controller is powered by a measurement module power source. In a further aspect, the electrical characteristic is resistance. In a still further aspect, the method includes (e) determining, by the controller, whether the present measurement is outside of the predetermined operational range, and (f) outputting, by the controller, a failure alert when the present measurement is found to be outside of the predetermined operational range.

In another aspect, the method includes (e) superimposing, by an alternating current (AC) signal generator connected to the CAN, an AC waveform over pulse signals communicated over the CAN, wherein the present measurement received in step (a) is based on the superimposed AC waveform. In a further aspect, the electrical characteristic is impedance. In a still further aspect, the method includes (f) determining, by the controller, whether the present measurement is outside of the predetermined operational range, and (g) outputting, by the controller, a failure alert when the present measurement is found to be outside of the predetermined operational range.

Still another example embodiment comprises a system for monitoring a controller area network (CAN) of a vehicle. The CAN has a high line and a low line that are connected to one another across two resistive element terminals. The CAN is connected to a plurality of nodes configured to send and/or receive communication over the CAN. The system includes a plurality of measurement modules. Each of the measurement modules is associated with a different location of the vehicle and has an electrical meter connected across the CAN configured to detect an electrical characteristic of the CAN. A controller is connected to each of the plurality of measurement modules. The controller is configured to: (a) receive a present measurement of the electrical characteristic of the CAN from each of the measurement modules, (b) for each of the measurement modules, determine, based on the present measurement and one or more previously stored measurements from the respective measurement module, whether the electrical characteristic is approaching an edge of a predetermined operational range for the electrical characteristic, and (c) when the electrical characteristic is found to be approaching the edge of the predetermined operational range for one or more of the measurement modules, output a deterioration warning and a location of at least one of the one or more measurement modules.

In one aspect, the electrical characteristic is at least one of resistance or impedance. In a further aspect, the electrical meter is an ohmmeter.

In another aspect, when the electrical characteristic is found to be approaching the edge of the predetermined operational range for two or more of the measurement modules, the controller is configured to output the location of only one of the two or more measurement modules. The location is selected based on (i) which of the two or more measurement modules has a present measurement closest to the edge of the predetermined operational range, or (ii) which of the two or more measurement modules experienced the greatest change between its present measurement and its one or more previously stored measurements.

In yet another aspect, when the electrical characteristic is found to be approaching the edge of the predetermined operational range for two or more of the measurement modules, the controller is configured to output the location of each of the two or more measurement modules.

In still another aspect, each of the measurement modules are incorporated into respective ones of the plurality of nodes.

### BRIEF DESCRIPTION OF THE SEVERAL VIEWS OF THE DRAWINGS

The following detailed description of preferred embodiments will be better understood when read in conjunction with the appended drawings. For the purpose of illustration, there are shown in the drawings embodiments which are presently preferred. It should be understood, however, that the invention is not limited to the precise arrangements and instrumentalities shown.

In the drawings:

FIG. 1 is a schematic block diagram of a partial communication network for a vehicle including a measurement module connected to a plurality of CANs in accordance with a first example embodiment;

FIG. 2 is a schematic block diagram of the measurement module of FIG. 1 and example component connections thereto;

FIG. 3 is a flow chart illustrating an example method for monitoring vehicle CAN condition performed using the measurement module of FIG. 1;

FIG. 4 is a schematic block diagram of a partial communication network for a vehicle including a measurement module connected to a CAN in accordance with a second example embodiment;

FIG. 5 is a schematic block diagram of a partial communication network for a vehicle including a plurality of measurement modules connected to a CAN and associated with various vehicle locations in accordance with a third example embodiment; and

FIG. 6 is a flow chart illustrating an example method for monitoring vehicle CAN condition performed using the measurement modules of FIG. 5.

### DETAILED DESCRIPTION

Certain terminology is used in the following description for convenience only and is not limiting. The words “right”, “left”, “lower”, and “upper” designate directions in the drawings to which reference is made. The words “inwardly” and “outwardly” refer to directions toward and away from, respectively, the geometric center of the device and designated parts thereof. The terminology includes the above-listed words, derivatives thereof, and words of similar import. Additionally, the words “a” and “an”, as used in the claims and in the corresponding portions of the specification, mean “at least one.”

It should also be understood that the terms “about,” “approximately,” “generally,” “substantially” and like terms, used herein when referring to a dimension or characteristic of a component, indicate that the described dimension/characteristic is not a strict boundary or parameter and does not exclude minor variations therefrom that are functionally similar. At a minimum, such references that include a numerical parameter would include variations that, using mathematical and industrial principles accepted in the art (e.g., rounding, measurement or other systematic errors, manufacturing tolerances, etc.), would not vary the least significant digit.

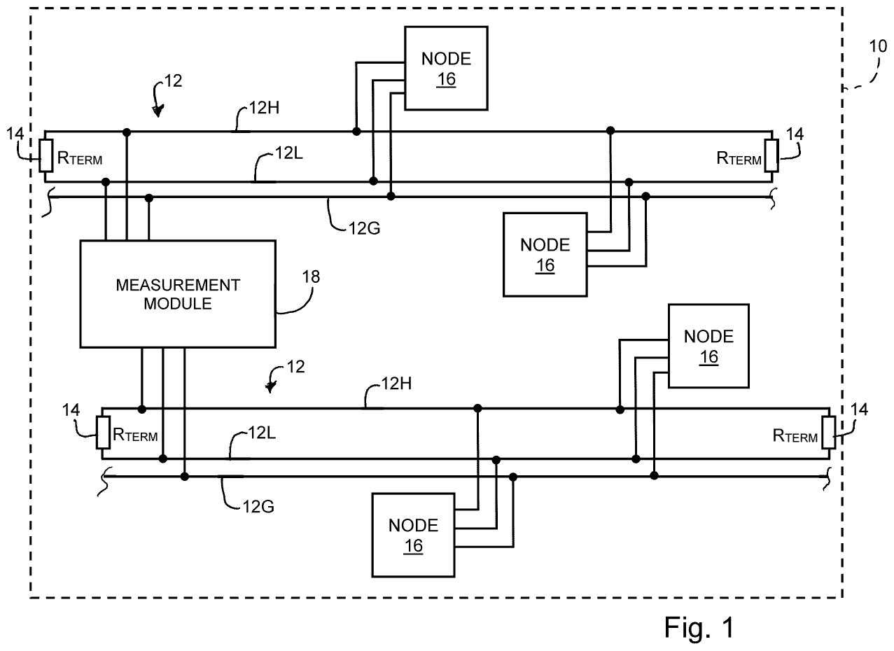

Referring to the drawings in detail, wherein like reference numerals indicate like elements throughout, FIG. 1 shows a vehicle 10, and in particular, a fire truck, including one or more CANs 12. Each CAN 12 may include a high line 12H and a low line 12L that are connected to one another across two terminals 14, which may comprise resistors or other resistance elements. In certain embodiments, the terminals 14 may each provide a terminal resistance R_{TERM} of 60Ω in normal operation, although other resistances (e.g., 120Ω or the like) may be used as well. The CANs 12 may include other circuitry for operation which, for simplicity, is not shown in the drawings. The CANs 12 may also have a shield or ground 12G associated therewith. A separate ground 12G can be provided for each separate CAN 12, or two or more CANs 12 may connect to a common ground 12G.

Each CAN 12 may be connected to one or more nodes 16, which may be electronic devices or systems related to an operation of the vehicle 10 and which may send or receive communications over the respective CAN 12 to which it is connected. Each CAN 12 may be dedicated to one or more specific operational aspects of the vehicle 10. For example, one CAN 12 may be dedicated to driving operations for the vehicle 10, and various nodes 16 thereof may relate to the engine, transmission, braking, steering, combinations thereof, or the like. Another CAN 12 may be dedicated to a pump control system of the vehicle, and the connected nodes 16 may relate to, for example, valves, a fire pump, related systems, combinations thereof, or the like. A still further CAN 12 may be dedicated to a foam chemical agent injection system, and the connected nodes 16 may, for example, relate to valves, level sensors, an injection pump, combinations thereof, or the like. Yet another CAN 12 may be dedicated to an aerial ladder system of the vehicle 10 and the connected nodes 16 may, for example, relate to hydraulic controls for the ladder or the like. The above-described CANs 12 and associated nodes 16 are examples only and are not intended to be limiting. Various operations can be combined into a single CAN or separated into multiple CANs, as desired, with appropriate nodes 16 connected thereto.

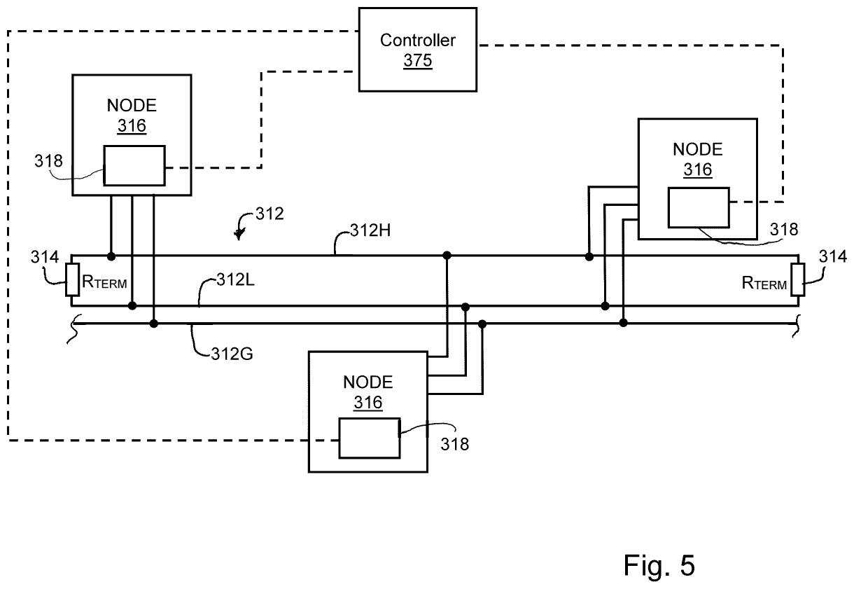

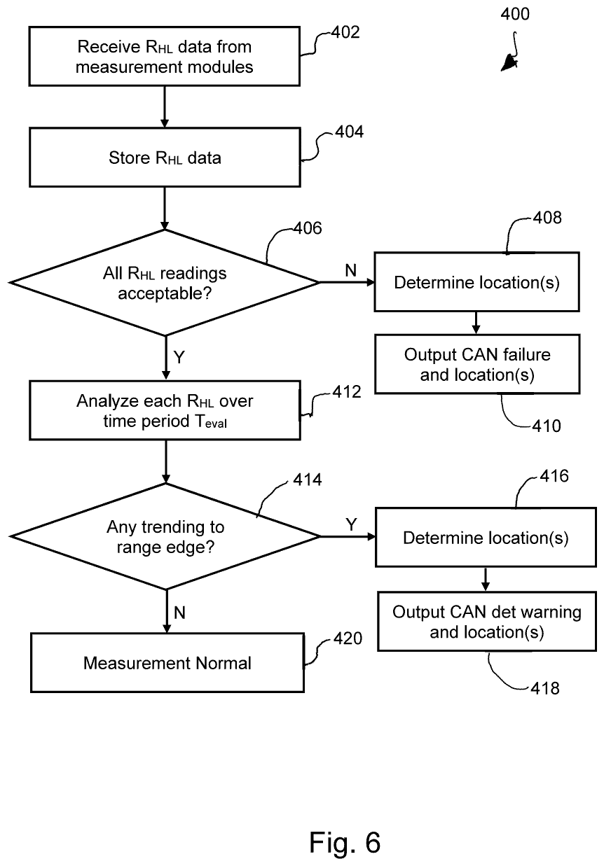

A measurement module 18 may be provided that may be connected to each of the CANs 12 for monitoring the condition thereof. For example, as shown in FIG. 1, the measurement module 18 may be connected across the high and low lines 12H, 12L of each CAN 12 as well as ground 12G for measuring the resistance, which can show whether a resistance across a CAN 12 is deteriorating and trending toward failure, whether the CAN 12 is improperly connected to a shield or ground 12G, or other like electrical faults and trends. Although one measurement module 18 is shown in FIG. 1, additional measurement modules 18 may be provided in certain embodiments, such as for providing redundancy, providing more specific locational deterioration information for the CAN (see e.g., an example provided in FIGS. 5-6), providing one or more CANs with their own dedicated measurement module 18, or the like.

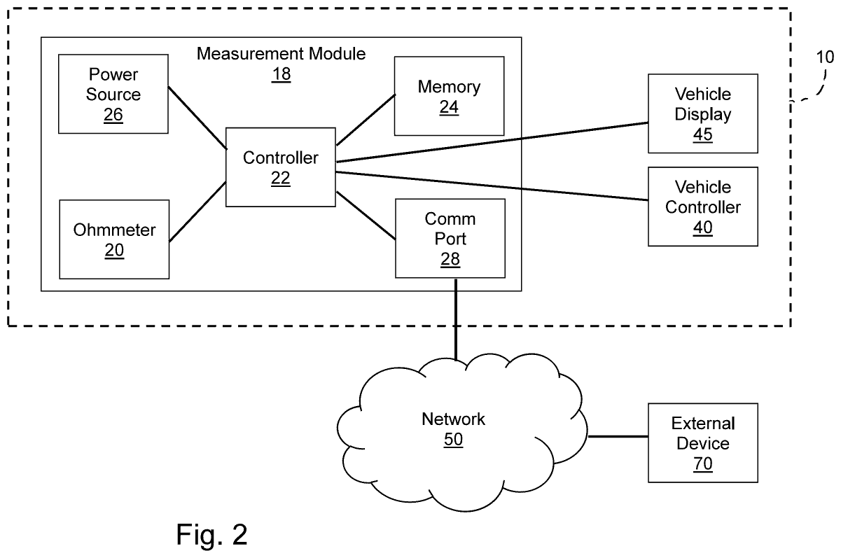

As seen in FIG. 2, the measurement module 18 may include one or more ohmmeters 20 for the purpose of measuring resistance of the CAN(s) 12. The measurement module 18 may include a separate ohmmeter 20 for each CAN 12 or may include a single ohmmeter 20 and a configurable switch (not shown) for connecting the ohmmeter 20 to a desired CAN 12. In still other embodiments, some CANs 12 may have their own dedicated ohmmeter 20 while others share a common ohmmeter 20.

Each ohmmeter 20 may connect to a controller 22 of the measurement module 18. The controller 22 may be a microcontroller unit (MCU), a central processing unit (CPU), a microprocessor, an application specific controller (ASIC), a programmable logic array (PLA), combinations thereof, or the like. The controller 22 may include or be coupled to a memory 24 that may store code or software for carrying out processes described herein and/or carrying out other operations of the measurement module 18 and may store any captured data for later transfer. It should be further appreciated that although the controller 22 is referred to in this example as a single component, the controller 22 may include a plurality of individual devices, with control functions divided among the individual devices. The controller 22 may be wired or wirelessly connected to components of the measurement module 18 and/or components external to the measurement module 18 necessary for carrying out the operations and processes described herein. The memory 24 is preferably non-volatile (e.g., hard disk drive, flash memory, or the like) to store measurements and other data even when the microcontroller 22 is powered down. In this manner, measurement trends, for example, may be monitored over time, as explained in further detail below.

The controller 22 may be connected to a power source 26 in the measurement module 18, which may also be used to power other components thereof, either directly or via the controller 22. The power source 26 may be a circuit connected to the battery (not shown) of the vehicle 10, and may include, for example, a voltage converter or other like conditioning circuitry to adapt appropriate voltage and current levels for use in the measurement module 18. In other embodiments, the power source 26 may be another source of electricity from the vehicle, or the power source 26 may be a dedicated battery contained within the measurement module 18.

The measurement module 18 may further include a communication port 28 that may include one or more of circuitry configured to communicate over one or more wired protocols, such as USB, Ethernet, IEEE 1394, I²C, or the like and/or one or more wireless protocols, such as WI-FI, BLUETOOTH, ZIGBEE, Z-WAVE, 3G, 4G, or 5G cellular, infrared, or the like. The communication port 28 may allow the measurement module 18 to communicate over a network 50, which may be a wide area network, such as the Internet, or other types of networks, including a local area network or the like. In this manner, the measurement module 18 may communicate with an external device 70 over the network 50. For example, the measurement module 18 may send measurement data and/or notifications to the external device 70. Similarly, the external device 70 may provide data or command signals to the measurement module 18. The external device 70 may be, for example, one or more of a mobile device (such as a smartphone, laptop, tablet, or the like, which may be accessing a website or an application), one or more servers, data storage, workstations, combinations thereof, or the like.

The controller 22 of the measurement module 18 may further be in communication with other systems in the vehicle 10. For example, the vehicle 10 may have a general vehicle controller 40 to which the controller 22 of the measurement module 18 reports. Like the controller 22, the vehicle controller 40 may be an MCU, CPU, microprocessor, ASIC, PLA, combinations thereof, or the like and include or be coupled to a memory (not shown) that may store code or software for carrying out processes associated with the vehicle 10 and may store any captured data for later transfer. Although vehicle controller 40 is referred to in this example as a single component, the vehicle controller 40 may include a plurality of individual devices, with control functions divided among the individual devices.

In the example shown in FIG. 2, data regarding the status of one or more CANs 12 may be reported by the controller 22 to the vehicle controller 40 for the vehicle controller 40 to take further action, such as alerting an operator, taking remedial action, combinations thereof, or the like. In some embodiments, the vehicle controller 40 may perform some or all of the functions of the controller 22 of the measurement module 18. For example, the ohmmeter(s) 20 may connect directly to the vehicle controller 40 and the vehicle controller 40 may analyze the resistance readings to determine a state of the CAN(s) 12 and/or report or take action on the results.

The vehicle 10 may further include a vehicle display 45, which may be located in a dashboard of the vehicle 10, an operational side panel, or elsewhere. The vehicle display 45 may be configured to output various operational conditions or selections (e.g., the vehicle display 45 may include traditional dashboard readouts such as speed, fuel level, and the like, may relate to status of a pump and/or include touchscreen inputs for pump operation, the chemical injection system, the ladder, combinations thereof, or the like) and/or alerts (e.g., component failures, errors, or the like) about the vehicle 10. The controller 22 of the measurement module 18 may be connected to the vehicle display 45 to provide, for example, the status of the CAN(s) 12 and/or information relating to any remedial action taken in response. While the controller 22 of the measurement module 18 is shown in FIG. 2 as being connected directly to the vehicle display 45, the controller 22 may send any data for reporting to the vehicle controller 40, which may then operate the vehicle display 45. Although one vehicle display 45 is shown, it is understood that the vehicle 10 may have any number of displays 45, any or all of which may be used for output and operation of the measurement module 18.

It should further be noted that the controller 22 of the measurement module 18 may, in some embodiments, use the communication port 28 to connect with one or both of the vehicle controller 40 and the vehicle display 45. In some instances, the controller 22 of the measurement module 18 may communicate with one or both of the vehicle controller 40 and the vehicle display 45 over the network 50. Although not shown in FIG. 2, the vehicle controller 40 may use the network to communicate with external devices 70, as well.

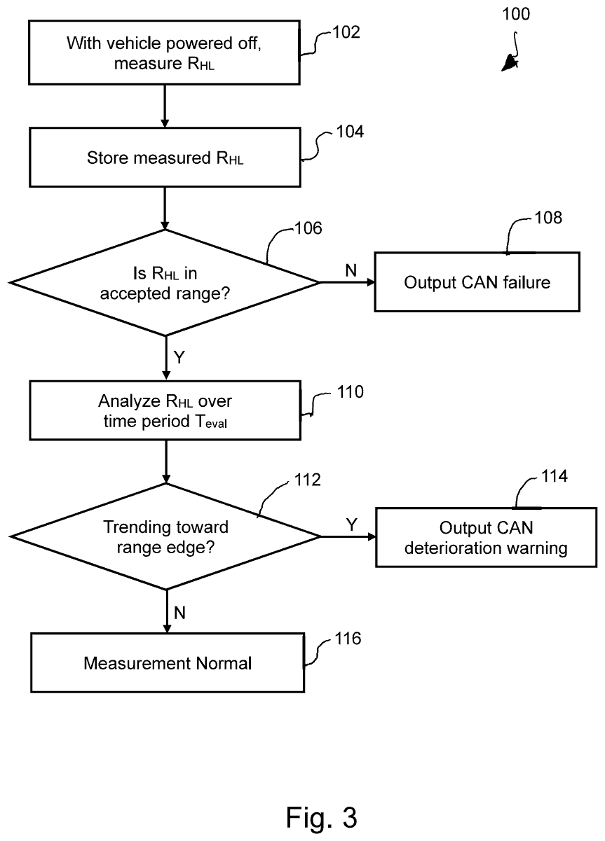

Referring to FIG. 3, an example method 100 for monitoring CAN 12 condition in a vehicle such as vehicle 10 shown in FIGS. 1-2. While the method 100 shown in FIG. 3 illustrates the monitoring of a single CAN 12, multiple CANs 12 may be tested and monitored, either sequentially or simultaneously. Prior to execution of the method 100, the vehicle 10 should be powered off—e.g., turning the ignition key to the “off” position, pressing the engine “start/stop” button, or the like. The measurement module 18, however, may remain on due to the power source 26 or the like for at least a period of time long enough to complete the measurements and, where necessary, the analysis described herein. At step 102, with the vehicle 10 powered off, the measurement module 18 may measure the resistance R_{HL} across the high and low lines 12H, 12L of the CAN 12. The measurement module 18 may take a single discrete measurement of the resistance R_{HL}, a string of measurements, an average measurement, or the like. At step 104, the measured resistance(s) R_{HL} may be stored, such as in memory 24 of the measurement module 18 or the like. As will be explained in further detail below, the measurements may be stored for further evaluation of trends that may indicate deterioration of the CAN 12 prior to failure.

At step 106, the measurement module 18 may determine whether the measured resistance R_{HL} is within an accepted range. For example, a specification for the resistance R_{HL} across the high and low lines 12H, 12L in a CAN 12 may be 60±6Ω. So, the measurement module 18 may determine whether the measured resistance R_{HL} is between 54-66Ω. If the measured resistance R_{HL} lies outside of that range, at step 108, the measurement module 18 may output that there is a failure of the CAN 12. Such an output may be made to the vehicle controller 40 for further action, to the vehicle display 45 to alert the operator of the vehicle 10, to external devices 70 on the network 50, via the communication port 28, combinations thereof, or the like. If, on the other hand, the measured resistance R_{HL} is within the acceptable range of operation, the measurement module 18 may continue to evaluate the CAN 12 condition.

For example, in step 110, the measurement module 18 may analyze the resistance R_{HL} values over some predetermined or adjustable time period Tₑᵥₐₗ. The time period Tₑᵥₐₗ may be defined in standard time durations (e.g., hours, days, weeks, months, or the like), number of prior measurements, combinations thereof, or the like. For example, the measurement module 18 may analyze the last ten measured resistances R_{HL}, the resistances R_{HL} measured over the last thirty days, or the like. At step 112, the measurement module 18 may determine whether the resistances R_{HL} over the time period Tₑᵥₐₗ are trending toward an edge of the range mentioned above for step 106 (or, in some examples, a smaller range within that range). As an example, the measurement module 18 may determine that the resistance R_{HL} has risen within the time period Tₑᵥₐₗ from 60Ω to 64Ω. The measurement module 18 may, as a result, determine that this trend indicates the CAN 12 is on its way toward failure. The controller 22 of the measurement module 18 may make such determinations based on, for example, stored comparative data or thresholds that may be set by the operator or based on historical data (e.g., the controller 22 may be programmed based on data stored in memory 24 or elsewhere to report a failure trend where a continual rise or fall over the time period Tₑᵥₐₗ or a portion thereof exceeds, for example, ±2Ω. In other embodiments, the controller 22 may include a suitable type of machine learning algorithm and/or neural network, such as deep learning algorithms, convolutional neural networks (CNN), or any other suitable machine learning algorithm and/or neural network capable of determining a trend in resistance R_{HL} changes tending toward failure of the CAN 12. Once the machine learning algorithm and/or neural network is trained, the resistance R_{HL} measurements over the time period Tₑᵥₐₗ may be input into the trained machine learning algorithm and/or neural network, which can then output data related to the determination made in step 112 shown in FIG. 3.

If the controller 22 determines at step 112 that the resistance R_{HL} measurements are trending toward the range edge or other failure threshold, then the controller 22 may, at step 114, output a warning regarding deterioration of the CAN 12. Such an output may be made to the vehicle controller 40 for further action, to the vehicle display 45 to alert the operator of the vehicle 10, to external devices 70 on the network 50, via the communication port 28, combinations thereof, or the like. If, on the other hand, the measured resistances R_{HL} are not trending in any significant way toward the range edge or other failure threshold, at step 116, the controller 22 may report (e.g., to vehicle controller 40, vehicle display 45, and/or external devices 70 over the network 50 or the like) or record (e.g., in memory 24 or the like) a normal measurement or otherwise take no action.

Although the method 100 in FIG. 3 is shown in terms of measuring and evaluating the resistance R_{HL} across the high and low lines 12H, 12L of the CAN 12, the measurement module 18 may also or alternatively measure and evaluate the resistance R_{HG} across the high and ground lines 12H, 12G of the CAN 12, and/or the resistance Rug across the low and ground lines 12L, 12G of the CAN 12 to check that there is no connection between the shield/ground line 12G and the high and/or low lines 12H, 12L and/or other signs of deterioration. When the measurement module 18 is measuring multiple resistances (e.g., R_{HL}, R_{HG}, and R_{LG}), the method 100 may be carried out sequentially for each resistance, simultaneously for each resistance, or in steps (e.g., all resistances are measured, then each is individually run through the analysis), combinations thereof, or the like.

While the method 100 depicted in FIG. 3 has been described above as being performed by the controller 22 of the measurement module 18, certain steps may be performed by the vehicle controller 40 or another controller (not shown) within the vehicle external to the measurement module 18. For example, the measurement module 18 may acquire the resistance measurements but send the data to, for example, the vehicle controller 40 for further analysis, such as steps 106 and/or 112. The vehicle controller 40 or other controller may command the measurement module 18 to perform, for example, the resistance measurement tasks.

While steps 106 and 112 are shown in FIG. 3 and described above as being performed separately and sequentially, these steps may be performed in parallel or may be combined into a single step. For example, when detecting whether the resistance is trending toward the acceptable range end, if the controller 22 (or other device performing the analysis) determines that the resistance has landed outside of the range, a failure of the CAN 12 may be determined.

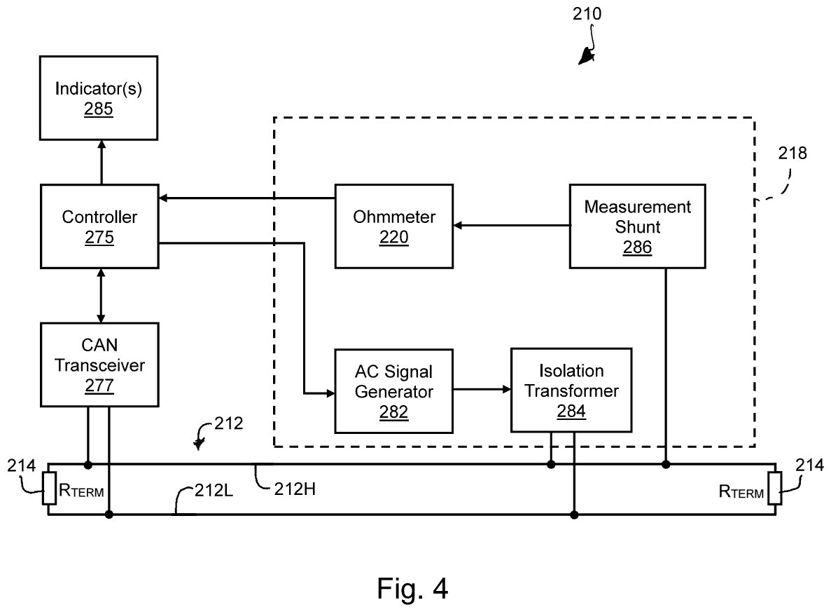

FIG. 4 shows an alternative example embodiment of a measurement system for a vehicle 210, which can determine the state of one or more CANs 212 while the vehicle 210 is still powered on. As before, each CAN 212 may include a high line 212H and a low line 212L connected across terminal resistors 214, which can provide terminal resistance R_{TERM} of 60 Ω, 120Ω, or the like in normal operation. It is to be understood that other components, such as a ground, nodes connected to the CAN 212, and other circuitry for operation may be included but are not shown in FIG. 4 for simplicity.

A measurement module 218 may be connected to a CAN 212. When multiple CANs 212 are present, the measurement module 218 may be connected to each or subsets thereof. Alternatively, each CAN 212 may have its own measurement module 218. The measurement module 218 in this example embodiment is configured to superimpose an alternating current signal over the pulse signals being sent and received over the CAN 212. Each CAN 212 may include a CAN transceiver 277 for sending/receiving signals over the CAN 212, and typically looking for pulse edges for reading the relevant data. The superimposed AC pulses may be tailored to avoid interference with the CAN transceiver 277 and can instead be used by the measurement module 218 to measure the impedance of the network physical layer (i.e., wiring) and the terminal resistors 214 of the CAN 212.

In this example, the measurement module 218 may include an AC signal generator 282 configured to generate an AC waveform to be applied to the CAN 212. The AC waveform may apply a voltage that may be an order of magnitude or lower than the voltage supplied on the CAN 212. CAN 212 pulses are typically in the range of 2-2.5 V, so the AC waveform voltage may be in the range of, for example, between 250-750 mV, such as about 500 mV. However, other voltages may be used as well. The frequency of the AC waveform may be in a range of between about 100-500 kHz, although other frequencies can be used as well. In addition, the AC waveform amplitude and/or frequency may be adjusted based on the characteristics of the CAN 212 signal, e.g., the frequency may be adjusted for higher bit rates of the CAN 212 signal. The AC signal generator 282 may provide the AC waveform to an isolation transformer 284 that may be part of the measurement module 218 and connected across the CAN 212, although other methods of introducing the AC waveform to the CAN 212 may be used as well.

The measurement module 218 may include a measurement shunt 286 separately connected to the CAN 212 that can utilized in connection with an ohmmeter 220 to calculate the network impedance of the terminal resistors 214. The ohmmeter 220 may communicate with a controller (not shown) of the measurement module 218, or may communicate directly with an external controller 275, such as a general vehicle controller, a designated CAN controller, or the like. In the example shown in FIG. 4, the ohmmeter 220 reports the impedance findings to controller 275 that facilitates CAN 212 communication via the CAN transceiver 277. The controller 275 (or other controller, such as within the measurement module) may store readings over time so as to determine if the network impedance is changing and trending toward deterioration. If network deterioration is detected, the controller 275 may output a signal to one or more indicators 285, which may be a vehicle display, computer monitor, indicator lights, or the like. The controller 275 may further communicate with the AC signal generator 282 so as to, for example, set or adjust voltage and frequency levels thereof, turn the signal on or off, and the like, although a controller within the measurement module 218 may also perform the same tasks, if desired. Measurements may be stored in a memory (not shown in FIG. 4), similar to the example embodiment described above.

A method for operating the measurement module 218 may be similar to that described above with respect to FIG. 3, although with the vehicle 210 powered on and the CAN 212 in operation. That is, with the AC signal being provided to the CAN 212, the controller 275 may determine whether the detected network impedance is within an accepted range, and if not, output an indication of CAN 212 failure, and also analyze the impedance over time so that if the impedance is trending toward an edge of the operational range, the controller 275 may output a deterioration warning.

The example provided in FIG. 4 may be supplemental to testing with the vehicle off, as well. For example, both methods can be used for redundancy and/or accuracy assessment.

In some embodiments, electrical characteristic measurements from the CAN may not only indicate the presence of deterioration or faults, but also their location within the vehicle. FIG. 5 shows an example system where a plurality of measurement modules 318 are placed at different locations along the CAN 312, and each of which reports to a centralized controller 375, such as a central vehicle controller, an external controller, or the like. Each measurement module 318 may be associated by the controller 375 with a particular region of the vehicle. For example, one measurement module 318 may be associated with a rear of the vehicle, one may be associated with the engine block, and the like. In the embodiment shown in FIG. 5, the measurement modules 318 are each incorporated (e.g., built-in, attached, or the like) within a respective node 316 distributed along the CAN 312. For example, a node 316 having a conventional primary function within the vehicle and CAN 312 may have a measurement module 318 embedded therein that only acts for the CAN 312 measurements separately from the other node 316 functionality (although possibly utilizing common components therein). However, the measurement modules 318 may be independently placed from the nodes 316 instead, or there may be combinations thereof. Using these location associations, the controller 375 may be able to identify a specific location associated with a fault so that it may be more easily found and corrected. Either of the measurement methods described above (i.e., measuring characteristics of the CAN 312 while the vehicle is powered off or superimposing an AC waveform over the CAN 312) may be used in this example.

An example method 400 is shown in FIG. 6 for conducting CAN measurements at multiple locations to more readily identify a region of the vehicle where a fault or deterioration may be occurring. At step 402, the controller 375 may receive may resistance R_{HL} data across the high and low lines 12H, 12L of the CAN 312 from each of the measurement modules 318. At step 404, the controller 375 may store the received R_{HL} data in memory (not shown in FIG. 5) for further evaluation. At step 406, the controller 375 may determine whether the R_{HL} data for each of the measurement modules 318 is within the accepted range. If any of the R_{HL}, data lies outside of that range, at step 408, the controller 375 may determine the associated location of the reporting measurement module 318. At step 410, the controller 375 may output, e.g., to the vehicle display, external device, or the like, that there is a failure of the CAN 312 and provide a location of the failure. If more than one measurement module 318 reports R_{HL}, data outside of the accepted range, the controller 375 may identify the measurement module 318 having the greatest deviation from the accepted range as the location to output with the failure alert. The idea is that the greatest deviation will occur closest to the fault, such as a defective connector or the like. In other embodiments, the controller 375 may simply output the location of each measurement module 318 reporting R_{HL} data out of range. In some embodiments, determinations of whether R_{HL} data lies within the acceptable range may be made by each measurement module 318 itself, and may simply report the failure to the central controller 375, possibly along with its location, which the controller 375 may then select for output.

If, on the other hand, the R_{HL} data for each of the measurement modules lies within the acceptable range of operation, the controller 375 may continue to step 412 to evaluate the R_{HL} data over some predetermined or adjustable time period Tₑᵥₐₗ. At step 414, the controller 375 may evaluate whether the R_{HL} data for any of the measurement modules 318 is trending toward an edge of the range mentioned above. If so, at step 416, the controller 375 may determine the associated location of the reporting measurement module 318. At step 418, the controller 375 may output, e.g., to the vehicle display, external device, or the like, a deterioration warning and provide a location of the problem. As before, if more than one measurement module 318 reports R_{HL} data trending toward the edge of the accepted range, the controller 375 may identify one measurement module 318 as the most probable location for investigation based on, for example, being the closest to the edge of the range, having the greatest change since last measurement, or the like. In other embodiments, the controller 375 may simply output the location of each measurement module 318 reporting R_{HL} data trending toward the edge of the range. In some embodiments, determinations of whether R_{HL} data is trending toward the edge of the range may be made by each measurement module 318 itself, and may simply report the findings to the central controller 375, possibly along with its location, which the controller 375 may then select for output.

If, on the other hand, the measured resistances R_{HL} for the measurement modules 318 are not trending in any significant way toward the range edge or other failure threshold, at step 420, the controller 375 may report (e.g., to the vehicle display and/or external devices or the like) or record (e.g., in memory or the like) a normal measurement or otherwise take no action.

While the measurement modules 18, 218, 318 are described as being used to measure resistances across various lines of a CAN 12, 212, 312, the measurement modules 18, 218, 318 may alternatively or also include other types of electrical meters (e.g., a voltmeter, ammeter, combinations thereof, or the like) for detecting other electrical characteristics that may be indicative of CAN 12 deterioration.

Using the systems described above, it is possible to reduce network failures on complex fire truck vehicles having multiple networks, some of which may have interdependent functions. Predicting which CAN 12, 212, 312 is out of specification and heading toward failure, and in some embodiments, where the causing fault is likely occurring, helps to narrow down areas where a problem might be centered and avoid costly failures during critical operating periods.

The systems described herein may operate automatically, e.g., the vehicle may be checking its networks continually or on a regular basis without operator intervention. In other embodiments, an operator may manually initiate a check by the system (e.g., through a user screen, test button, or like interface) when an issue is suspected, when the vehicle is undergoing maintenance, or at other times where network status is desired to be checked.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

While specific and distinct embodiments have been shown in the drawings, various individual elements or combinations of elements from the different embodiments may be combined with one another while in keeping with the spirit and scope of the invention. Thus, an individual feature described herein only with respect to one embodiment should not be construed as being incompatible with other embodiments described herein or otherwise encompassed by the invention.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined herein.

We claim:

1. A system for monitoring a controller area network (CAN) of a vehicle, the CAN having a high line and a low line that are connected to one another across two resistive element terminals, the CAN being connected to one or more nodes configured to send and/or receive communication over the CAN, the system comprising:
a measurement module power source;
an electrical meter connected across the CAN and configured to detect an electrical characteristic of the CAN;
a memory configured to store one or more prior measurements of the electrical characteristic by the electrical meter; and
a controller connected to the measurement module power source, the electrical meter, and the memory, the controller being configured to, when the vehicle is powered off and the controller is powered by the measurement module power source:
(a) receive a present measurement of the electrical characteristic of the CAN from the electrical meter,
(b) determine, based on the present measurement and the one or more prior measurements, whether the electrical characteristic is approaching an edge of a predetermined operational range for the electrical characteristic, and
(c) output a deterioration warning when the electrical characteristic is found to be approaching the edge of the predetermined operational range.

2. The system of claim 1, wherein the electrical characteristic is resistance.

3. The system of claim 2, wherein the electrical meter is an ohmmeter.

4. The system of claim 1, further comprising a communication port connected to the controller.

5. The system of claim 4, wherein the communication port is configured to connect to a network, and the controller outputs the deterioration to the communication port for sending to an external device via the network.

6. The system of claim 1, wherein the controller is further configured to:
(d) determine whether the present measurement is outside of the predetermined operational range, and
(e) output a failure alert when the present measurement is found to be outside of the predetermined operational range.

7. The system of claim 1, wherein the controller is configured to output the deterioration warning to a vehicle display output.

8. A system for monitoring a controller area network (CAN) of a vehicle, the CAN having a high line and a low line that are connected to one another across two resistive element terminals, the CAN being connected to one or more nodes configured to send and/or receive communication over the CAN, the system comprising:
an alternating current (AC) signal generator connected to the CAN and configured to superimpose an AC waveform over pulse signals communicated over the CAN;
an electrical meter connected to the CAN and configured to detect an electrical characteristic of the CAN;
a memory configured to store one or more prior measurements of the electrical characteristic by the electrical meter; and
a controller connected to the AC signal generator, the electrical meter, and the memory, the controller being configured to:
(a) receive a present measurement of the electrical characteristic of the CAN from the electrical meter based on the superimposed AC waveform,
(b) determine, based on the present measurement and the one or more prior measurements, whether the electrical characteristic is approaching an edge of a predetermined operational range for the electrical characteristic, and
(c) output a deterioration warning when the electrical characteristic is found to be approaching the edge of the predetermined operational range.

9. The system of claim 8, wherein the electrical characteristic is impedance.

10. The system of claim 9, wherein the electrical meter is an ohmmeter.

11. The system of claim 10, further comprising a measurement shunt connected between the ohmmeter and the CAN.

12. The system of claim 8, further comprising an isolation transformer connected between the AC signal generator and the CAN.

13. The system of claim 8, wherein the controller is further configured to:
(d) determine whether the present measurement is outside of the predetermined operational range, and
(e) output a failure alert when the present measurement is found to be outside of the predetermined operational range.

14. A method of monitoring a controller area network (CAN) of a vehicle, the CAN having a high line and a low line that are connected to one another across two resistive element terminals, the CAN being connected to one or more nodes configured to send and/or receive communication over the CAN, the method comprising:
(a) receiving, by a controller from an electrical meter, a present measurement of an electrical characteristic of the CAN;
(b) retrieving, by the controller from a memory, one or more prior measurements of the electrical characteristic;
(c) determining, by the controller, based on the present measurement and the one or more prior measurements, whether the electrical characteristic is approaching an edge of a predetermined operational range for the electrical characteristic; and
(d) outputting, by the controller, a deterioration warning when the electrical characteristic is found to be approaching the edge of the predetermined operational range.

15. The method of claim 14, wherein the controller performs steps (a)-(d) while the vehicle is powered off and the controller is powered by a measurement module power source.

16. The method of claim 15, wherein the electrical characteristic is resistance.

17. The method of claim 15, further comprising:
(e) determining, by the controller, whether the present measurement is outside of the predetermined operational range, and
(f) outputting, by the controller, a failure alert when the present measurement is found to be outside of the predetermined operational range.

18. The method of claim 14, wherein the method further comprises
(e) superimposing, by an alternating current (AC) signal generator connected to the CAN, an AC waveform over pulse signals communicated over the CAN,
wherein the present measurement received in step (a) is based on the superimposed AC waveform.

19. The method of claim 18, wherein the electrical characteristic is impedance.

20. The method of claim 19, further comprising:
(f) determining, by the controller, whether the present measurement is outside of the predetermined operational range, and
(g) outputting, by the controller, a failure alert when the present measurement is found to be outside of the predetermined operational range.

21. A system for monitoring a controller area network (CAN) of a vehicle, the CAN having a high line and a low line that are connected to one another across two resistive element terminals, the CAN being connected to a plurality of nodes configured to send and/or receive communication over the CAN, the system comprising:
a plurality of measurement modules, each of the measurement modules being associated with a different location of the vehicle and having an electrical meter connected across the CAN configured to detect an electrical characteristic of the CAN; and
a controller connected to each of the plurality of measurement modules, the controller being configured to:
(a) receive a present measurement of the electrical characteristic of the CAN from each of the measurement modules,
(b) for each of the measurement modules, determine, based on the present measurement and one or more previously stored measurements from the respective measurement module, whether the electrical characteristic is approaching an edge of a predetermined operational range for the electrical characteristic, and
(c) when the electrical characteristic is found to be approaching the edge of the predetermined operational range for one or more of the measurement modules, output a deterioration warning and a location of at least one of the one or more measurement modules.

22. The system of claim 21, wherein the electrical characteristic is at least one of resistance or impedance.

23. The system of claim 22, wherein the electrical meter is an ohmmeter.

24. The system of claim 21, wherein when the electrical characteristic is found to be approaching the edge of the predetermined operational range for two or more of the measurement modules, the controller is configured to output the location of only one of the two or more measurement modules, the location being selected based on (i) which of the two or more measurement modules has a present measurement closest to the edge of the predetermined operational range, or (ii) which of the two or more measurement modules experienced the greatest change between its present measurement and its one or more previously stored measurements.

25. The system of claim 21, wherein when the electrical characteristic is found to be approaching the edge of the predetermined operational range for two or more of the measurement modules, the controller is configured to output the location of each of the two or more measurement modules.

26. The system of claim 21, wherein each of the measurement modules are incorporated into respective ones of the plurality of nodes.
